(19) United States
(12) Patent Application Publication
(10) Pub. No.: US 2006/0081888 A1
(43) Pub. Date: Apr. 20, 2006

(54) Solid-state image sensor

(75) Inventor: Masahiro Oda, Itami-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/229,760

(22) Filed: Sep. 20, 2005

(30) Foreign Application Priority Data
Oct. 20, 2004 (JP) JP2004-305125

(51) Int. Cl. H01L 29/768

(52) U.S. Cl. 257/215

(57) ABSTRACT

A solid-state image sensor capable of suppressing mixture of charge between adjacent charge transfer paths (charge transfer regions), and suppressing reduction of a transfer efficiency of charge is provided. In the solid-state image sensor, the charge transfer region includes a first region with a first channel width, and a second region with a second channel width smaller than the first channel width. A boundary part of the charge transfer region between the first region with the first channel width and the second region with the second channel width is located in a region between two transfer electrodes adjacent to each other.

### BACKGROUND OF THE INVENTION

1. Field of the Invention

The present invention relates to a solid-state image sensor, and more particularly to a solid-state image sensor comprising a plurality of separation regions.

2. Description of the Background Art

A solid-state image sensor comprising a plurality of separation regions is known in general. This type of solid-state image sensor is disclosed in Japanese Patent Laying-Open No. HEI 8-139998, for example.

FIG. 10 is a plan view for illustrating a structure of a storage part and a horizontal transfer part of an exemplary conventional solid-state image sensor with a structure similar to the aforementioned solid-state image sensor disclosed in Japanese Patent Laying-Open No. HEI 8-139998. FIG. 11 shows a state of a potential in transfer of electrons in a region where the storage part and the horizontal transfer part of the exemplary conventional solid-state image sensor shown in FIG. 10 are connected to each other. With reference to FIG. 10, the exemplary conventional solid-state image sensor comprises a storage part 301 and a horizontal transfer part 302. The storage part 301 serves to store electrons transferred from an imaging part (not shown) that performs photoelectric conversion, and to transfer the electrons in the vertical direction to the horizontal transfer part 302. The horizontal transfer part 302 serves to sequentially transfer the electrons transferred from the storage part 301 in the horizontal direction to the output part (not shown). The transferred electrons are provided from the output part (not shown) as an electrical signal.

The storage part 301 and the horizontal transfer part 302 are provided with a charge transfer path 303 composing a channel where electrons are transferred. The charge transfer path 303 is composed of a plurality of vertical charge transfer paths 303a that are provided to extend in the vertical direction in the storage part 301 and a prescribed part of the horizontal transfer part 302, and one horizontal charge transfer path 303b that is provided to extend in the horizontal direction in the horizontal transfer part 302. All of the plurality of vertical charge transfer paths 303a are connected to the one horizontal charge transfer path 303b. A plurality of vertical transfer electrodes 304 for transferring electrons in the vertical charge transfer paths 303a in the vertical direction are provided in the storage part 301 to extend in the horizontal direction. The plurality of vertical transfer electrodes 304 of the storage part 301 are configured to receive three-phase clock signals for transferring electrons. In the storage part 301, three vertical transfer electrodes 304 are turned to ON state one time each by the three-phase clock signals, thus, electrons stored in a region under a prescribed vertical transfer electrode 304 are transferred to a region under other vertical transfer electrode 304 adjacent to the prescribed vertical transfer electrode 304. In addition, a plurality of horizontal transfer electrodes 305a and 305b for transferring electrons in the horizontal charge transfer path 303b in the horizontal direction are provided in the horizontal transfer part 302 to extend in the vertical direction. The plurality of horizontal transfer electrodes 305a and 305b receive clock signals for transferring electrons, respectively. The plurality of horizontal transfer electrodes 305a and 305b are turned to ON state one time each by the clock signals, thus, electrons stored in a region under a prescribed horizontal transfer electrode 305a (305b) are sequentially transferred to a region under other horizontal transfer electrode 305b (305a) adjacent to the prescribed horizontal transfer electrode 305a (305b).

A plurality of p-type channel stop regions 306 that are arranged so as to interpose the vertical charge transfer path 303a between them are provided in the storage part 301 and the horizontal transfer part 302 to extend in the horizontal direction. As shown in FIG. 10, the p-type channel stop regions 306 is composed of a region 306a that is provided in the storage part 301 and has a width W3, and a region 306b that is provided in the horizontal transfer part 302 and has a width W4 larger than the width W3. The region 306b of the p-type channel stop region 306 with the larger width W4 is provided in order to suppress that electrons in two adjacent vertical charge transfer paths 303a that interpose the region 306b of the p-type channel stop region 306 between them are mixed. A channel width W2 of the vertical charge transfer path 303a that is interposed between the regions 306b of adjacent two p-type channel stop regions 306 is smaller than a channel width W1 of the vertical charge transfer path 303a that is interposed between the regions 306a of adjacent two p-type channel stop regions 306. In a boundary part 303c between the vertical charge transfer path 303a that is interposed between the regions 306a of adjacent two p-type channel stop regions 306 and the vertical charge transfer path 303a that is interposed between the regions 306b of adjacent two p-type channel stop regions 306, because of increase of a narrow channel effect by an electric field from the adjacent p-type channel stop regions 306 due to the smaller channel width of the vertical charge transfer path 303a, a potential barrier shown in FIG. 11 is formed. Note that FIG. 11 shows a potential state when a prescribed negative voltage is applied to the vertical transfer electrode 304, and a prescribed positive voltage is applied to the horizontal transfer electrode 305a. The boundary part 303c between the vertical charge transfer path 303a that is interposed between the regions 306a of adjacent two p-type channel stop regions 306 and the vertical charge transfer path 303a that is interposed between the regions 306b of adjacent two p-type channel stop regions 306 is located under the center position of the transfer electrode 304 of the final stage in the storage part 301. That is, the boundary part 303c where the channel width of the vertical charge transfer path 303a reduces is located under the center position of the transfer electrode 304 of the final stage in the storage part 301. In the exemplary conventional solid-state image sensor, in the final step where electrons are transferred from the storage part 301 to the horizontal transfer part 302, a prescribed negative voltage is applied to the vertical transfer electrode 304 of the final stage of the storage part 301, and a prescribed positive voltage is applied to the horizontal transfer electrode 305a.

However, in the exemplary conventional solid-state image sensor shown in FIG. 10, in the case where the region 306b with the larger width W4 is provided in the p-type channel stop region 306 in order to suppress that electrons in two adjacent vertical charge transfer paths 303a are mixed, there is a disadvantage that a potential barrier is formed in the boundary part 303c where the channel width of the vertical charge transfer path 303a reduces as shown in FIG. 11. Consequently, since the potential barrier interferes with transfer of electrons from the storage part 301 to the horizontal transfer part 302, there is a problem that a transfer efficiency of electrons reduces. Particularly, as pixel size is getting smaller, in the case where a ratio of the channel width W2 of the vertical charge transfer path 303a that is interposed between the regions 306b of adjacent two p-type channel stop regions 306 to the channel width W1 of the vertical charge transfer path 303a that is interposed between regions 306a of adjacent two p-type channel stop regions 306 becomes smaller, a potential barrier further tends to appear due to more increase of a narrow channel effect by an electric field from the adjacent p-type channel stop regions 306. In this case, the aforementioned problem that a transfer efficiency of electrons reduces is more remarkable.

### SUMMARY OF THE INVENTION

The present invention is aimed at solving the above problems, and it is one object of the present invention to provide a solid-state image sensor capable of suppressing mixture of charge between adjacent charge transfer paths (charge transfer regions), and suppressing reduction of a transfer efficiency of charge.

To achieve the above object, a solid-state image sensor according to a first aspect of the present invention comprises a plurality of transfer electrodes that are arranged in a charge transfer region composing a channel for transferring charge and transfer the charge, and a plurality of separation regions that are arranged so as to interpose the charge transfer region between them, and the charge transfer region includes a first region with a first channel width, and a second region with a second channel width smaller than the first channel width, and a boundary part of the charge transfer region between the first region with the first channel width and the second region with the second channel width is located in a region between two of the transfer electrodes adjacent to each other.

In the solid-state image sensor according to the first aspect, the boundary part of the charge transfer region between the first region with the first channel width and the second region with the second channel width smaller than the first channel width is located in a region between two of the transfer electrodes adjacent to each other as mentioned above, thus, in the case where a prescribed negative voltage is applied to the transfer electrode on the opposite side of a transfer direction of charge of the two of the transfer electrodes adjacent to each other, and a positive voltage is applied to the transfer electrode on the transfer direction side of charge, an electric field is generated between the two of the transfer electrodes adjacent to each other toward the transfer direction of charge. The generated electric field can cancel a potential barrier that is formed in the boundary part between the first region with the first channel width and the second region with the second channel width due to increase of a narrow channel effect by an electric field from the separation region as a channel width reduces. Therefore, since interference with transfer of charge by the potential barrier can be suppressed, it is possible to suppress reduction of a transfer efficiency of charge. In addition, since the plurality of separation regions are arranged so as to interpose the charge transfer region between them, and the first region with the first channel width and the second region with the second channel width smaller than the first channel width are provided in the charge transfer region, a width of the separation region adjacent to the second region with the second channel width of the charge transfer region can be larger than a width of the separation region adjacent to the first region with the first channel width of the charge transfer region. Therefore, a region with a larger width of the separation region can suppress mixture of charge between adjacent charge transfer regions that interpose the separation region between them.

In the aforementioned solid-state image sensor according to the first aspect, preferably, the second region with the second channel width smaller than the first channel width is located on a transfer direction side relative to the first region with the first channel width. In this constitution, since a width of the separation region adjacent to the second region with the second channel width on the charge transfer direction side of the charge transfer region can be larger than a width of the separation region adjacent to the first region with the first channel width of the charge transfer region, a region with a larger width of the separation region on the charge transfer direction side can suppress mixture of charge between adjacent charge transfer regions that interpose the separation region between them.

In the aforementioned solid-state image sensor according to the first aspect, preferably, the separation region includes a region with a first width that is provided adjacent to the first region with the first channel width of the charge transfer region, and a region with a second width larger than the first width that is provided adjacent to the second region with the second channel width of the charge transfer region. In this constitution, the first region with the first channel width can be easily formed between the regions with the first width of two of the separation regions adjacent to each other, and the second region with the second channel width smaller than the first channel width can be easily formed between the regions with the second width larger than the first width of two of the separation regions adjacent to each other.

In the aforementioned solid-state image sensor according to the first aspect, preferably, in transfer of the charge, a positive voltage is applied to the transfer electrode on a transfer direction side of the charge of the two of the transfer electrodes adjacent to each other, and a negative voltage with an absolute value of the voltage larger than the positive voltage is applied to the transfer electrode on the opposite side of the transfer direction side of the charge of the two of the transfer electrodes adjacent to each other. In this constitution, since an electric field can be easily generated between the two of the transfer electrodes adjacent to each other toward the transfer direction of charge, the electric field can easily cancel a potential barrier that is formed in the boundary part between the first region with the first channel width and the second region with the second channel width between the two of the transfer electrodes adjacent to each other.

In the aforementioned solid-state image sensor according to the first aspect, preferably, the boundary part between the first region with the first channel width and the second region with the second channel width is located in a location closer to an end of the transfer electrode on the opposite side of a transfer direction of the charge relative to an intermediate location between the two of the transfer electrodes adjacent to each other. In this constitution, in the case where a positive voltage is applied to the transfer electrode on a transfer direction side of the charge of the two of the transfer electrodes adjacent to each other, and a negative voltage with an absolute value of the voltage larger than the positive voltage of the transfer electrode on the transfer direction side of the charge is applied to the transfer electrode on the opposite side of the transfer direction side of charge, since an electric field toward the transfer direction of charge increases as closer to the end of the transfer electrode on the opposite side of the transfer direction of charge in between the two of the transfer electrodes adjacent to each other, it is possible to apply a larger electric field to the boundary part between the first region with the first channel width and the second region with the second channel width that is located in a location closer to the end of the transfer electrode on the opposite side of the transfer direction of charge relative to the intermediate location between the two of the transfer electrodes adjacent to each other. Therefore, it is possible to further ensure to cancel a potential barrier that is formed in the boundary part of the charge transfer region between the first region with the first channel width and the second region with the second channel width.

In the aforementioned solid-state image sensor according to the first aspect, preferably, the charge transfer region is composed of a first conductive type first impurity region, and the separation region is composed of a second conductive type second impurity region. In this constitution, the separation region composed of the second conductive type second impurity region can easily separate the charge transfer region composed of the first conductive type first impurity region.

In this case, preferably, the sensor further comprises a first conductive type semiconductor substrate having the first impurity region composing the charge transfer region and the second impurity region composing the separation region that are formed in its main surface, and a second conductive type third impurity region that is formed in the main surface of the first conductive type semiconductor substrate so as to have a depth larger than the first and second impurity regions, and the first conductive type first impurity region is formed in a main surface of the second conductive type third impurity region. In this constitution, it is possible to pull out electrons that overflow from a potential well of the first impurity region storing electrons through the second conductive type third impurity region toward the first conductive type semiconductor substrate side.

In the aforementioned solid-state image sensor according to the first aspect, preferably, the charge transfer region includes a vertical transfer region that transfers the charge in the vertical direction and a horizontal transfer region that is connected to the vertical transfer region and transfers the charge transferred from the vertical transfer region in the horizontal direction, and the transfer electrode includes a vertical transfer electrode that transfers the charge in the vertical transfer region and a horizontal transfer electrode that transfers the charge in the horizontal transfer region, and the boundary part of the charge transfer region between the first region with the first channel width and the second region with the second channel width is located in a region between the vertical transfer electrode and the horizontal transfer electrode adjacent to each other in a region where the vertical transfer region and the horizontal transfer region are connected to each other. In this constitution, in the case where, in the region where the vertical transfer region and the horizontal transfer region are connected to each other, a prescribed negative voltage is applied to the vertical transfer electrode, and a prescribed positive voltage is applied to the horizontal transfer electrode, since an electric field is generated between the vertical transfer electrode and the horizontal transfer electrode adjacent to each other toward the transfer direction of charge, the generated electric field can cancel a potential barrier that is formed in the boundary part of the charge transfer region between the first region with the first channel width and the second region with the second channel width due to increase of a narrow channel effect by an electric field from the separation region as a channel width reduces. Therefore, it is possible to suppress interference with transfer of charge from the vertical transfer region to the horizontal transfer region by the potential barrier. In addition, the boundary part of the charge transfer region between the first region with the first channel width and the second region with the second channel width is located in a region between the vertical transfer electrode and the horizontal transfer electrode adjacent to each other, thus, in the case where the second region with the smaller second channel width of the charge transfer region is located on the horizontal transfer electrode side, and charge in one vertical transfer region is transferred to a region under one horizontal transfer electrode corresponding thereto, a region with a larger width of the separation region adjacent to the second region of the vertical transfer region can effectively suppress that charge transferred to the region under the one horizontal transfer electrode flows to a region under adjacent other horizontal transfer electrode through the separation region and vicinity thereof. Therefore, it is possible to ensure to transfer charge in one vertical transfer region to a region under one horizontal transfer electrode corresponding thereto.

In the solid-state image sensor comprising the vertical transfer region and the horizontal transfer region, the vertical transfer region includes a storage part that stores signal charge, and the horizontal transfer region includes a horizontal transfer part that transfers the signal charge from the storage part to an output part, wherein the boundary part between the first region with the first channel width and the second region with the second channel width is located in a region between the vertical transfer electrode and the horizontal transfer electrode adjacent to each other in a region where the storage part and the horizontal transfer part are connected to each other. In this constitution, it is possible to suppress mixture of charge between the storage part and the horizontal transfer part to each other, and to suppress reduction of a transfer efficiency of charge. In this case, the second region is formed to extend to a region under the horizontal transfer electrode of the horizontal transfer part. In this constitution, the second region that extends to the region under the horizontal transfer electrode can easily transfer charge from the storage part to the horizontal transfer part.

A solid-state image sensor according to a second aspect of the present invention comprises a plurality of transfer electrodes that are arranged in a charge transfer region composing a channel for transferring charge and transfer the charge, and a plurality of separation regions that are arranged so as to interpose the charge transfer region between them, wherein the charge transfer region includes a first region with a first channel width, and a second region with a second channel width smaller than the first channel width, and a boundary part of the charge transfer region between the first region with the first channel width and the second region with the second channel width is located in a region between two of the transfer electrodes adjacent to each other, or in a region in the vicinity of a position beneath an end of the transfer electrode on the opposite side of a transfer direction of the charge relative to the two of the transfer electrodes adjacent to each other.

In the solid-state image sensor according to the second aspect, the boundary part of the charge transfer region between the first region with the first channel width and the second region with the second channel width smaller than the first channel width is located in the region between two of the transfer electrodes adjacent to each other, or in the region in the vicinity of the position beneath the end of the transfer electrode on the opposite side of the transfer direction of the charge relative to the two of the transfer electrodes adjacent to each other as mentioned above, thus, in the case where a prescribed negative voltage is applied to the transfer electrode on the opposite side of the transfer direction of charge of the two of the transfer electrodes adjacent to each other, and a positive voltage is applied to the transfer electrode on the transfer direction side of charge, an electric field is generated in the region between the two of the transfer electrodes adjacent to each other, or in the region in the vicinity of the position beneath the end of the transfer electrode on the opposite side of the transfer direction of the charge relative to the two of the transfer electrodes adjacent to each other toward the transfer direction of charge. The generated electric field can cancel a potential barrier that is formed in the boundary part between the first region with the first channel width and the second region with the second channel width due to increase of a narrow channel effect by an electric field from the separation region as a channel width reduces. Therefore, since interference with transfer of charge by the potential barrier can be suppressed, it is possible to suppress reduction of a transfer efficiency of charge. In addition, since the plurality of separation regions are arranged so as to interpose the charge transfer region between them, and the first region with the first channel width and the second region with the second channel width smaller than the first channel width are provided in the charge transfer region, a width of the separation region adjacent to the second region with the second channel width of the charge transfer region can be larger than a width of the separation region adjacent to the first region with the first channel width of the charge transfer region. Therefore, a region with a larger width of the separation region can suppress mixture of charge between adjacent charge transfer regions that interpose the separation region between them.

In the aforementioned solid-state image sensor according to the second aspect, the boundary part of the charge transfer region between the first region with the first channel width and the second region with the second channel width may be located in a region in the vicinity of the position beneath the end of the transfer electrode on the opposite side of the transfer direction of the charge relative to the two of the transfer electrodes adjacent to each other. In this constitution, in the case where a positive voltage is applied to the transfer electrode on the transfer direction side of the charge of the two of the transfer electrodes adjacent to each other, and a negative voltage with an absolute value of the voltage larger than the positive voltage of the transfer electrode on the transfer direction side of the charge is applied to the transfer electrode on the opposite side of the transfer direction side of charge, since an electric field that is generated between the vertical transfer electrode and the horizontal transfer electrode toward the transfer direction of charge also affects the region in the vicinity of the position beneath the end on the horizontal transfer electrode side of the vertical transfer electrode, it is possible to cancel a potential barrier in the region in the vicinity of the position beneath the end on the horizontal transfer electrode side of the vertical transfer electrode.

In the aforementioned solid-state image sensor according to the second aspect, the boundary part of the charge transfer region between the first region with the first channel width and the second region with the second channel width may be located in a location closer to an end of the transfer electrode on the opposite side of the transfer direction of the charge relative to an intermediate location between the two of the transfer electrodes adjacent to each other. In this constitution, in the case where a positive voltage is applied to the transfer electrode on the transfer direction side of the charge of the two of the transfer electrodes adjacent to each other, and a negative voltage with an absolute value of the voltage larger than the positive voltage of the transfer electrode on the transfer direction side of the charge is applied to the transfer electrode on the opposite side of the transfer direction side of charge, since an electric field toward the transfer direction of charge increases as closer to the end of the transfer electrode on the opposite side of the transfer direction of charge in between the two of the transfer electrodes adjacent to each other, it is possible to apply a larger electric field to the boundary part between the first region with the first channel width and the second region with the second channel width that is located in a location closer to the end of the transfer electrode on the opposite side of the transfer direction of charge relative to the intermediate location between the two of the transfer electrodes adjacent to each other. Therefore, it is possible to further ensure to cancel a potential barrier that is formed in the boundary part of the charge transfer region between the first region with the first channel width and the second region with the second channel width.

In the aforementioned solid-state image sensor according to the second aspect, preferably, the second region with the second channel width smaller than the first channel width is located on the transfer direction side relative to the first region with the first channel width. In this constitution, since a width of the separation region adjacent to the second region with the second channel width on the charge transfer direction side of the charge transfer region can be larger than a width of the separation region adjacent to the first region with the first channel width of the charge transfer region, a region with a larger width of the separation region on the charge transfer direction side can suppress mixture of charge between adjacent charge transfer regions that interpose the separation region between them.

In the aforementioned solid-state image sensor according to the second aspect, preferably, the separation region includes a region with a first width that is provided adjacent to the first region with the first channel width of the charge transfer region, and a region with a second width larger than the first width that is provided adjacent to the second region with the second channel width of the charge transfer region. In this constitution, the first region with the first channel width can be easily formed between the regions with the first width of two of the separation regions adjacent to each other, and the second region with the second channel width smaller than the first channel width can be easily formed between the regions with the second width larger than the first width of two of the separation regions adjacent to each other.

In the aforementioned solid-state image sensor according to the second aspect, preferably, in transfer of the charge, a positive voltage is applied to the transfer electrode on the transfer direction side of the charge of the two of the transfer electrodes adjacent to each other, and a negative voltage with an absolute value of the voltage larger than the positive voltage is applied to the transfer electrode on the opposite side of the transfer direction side of the charge of the two of the transfer electrodes adjacent to each other. In this constitution, since an electric field can be easily generated between the two of the transfer electrodes adjacent to each other toward the transfer direction of charge, the electric field can easily cancel a potential barrier that is formed in the boundary part between the first region with the first channel width and the second region with the second channel width between the two of the transfer electrodes adjacent to each other.

In the aforementioned solid-state image sensor according to the second aspect, preferably, the charge transfer region is composed of a first conductive type first impurity region, and the separation region is composed of a second conductive type second impurity region. In this constitution, the separation region composed of the second conductive type second impurity region can easily separate the charge transfer region composed of the first conductive type first impurity region.

In this case, preferably, the sensor further comprises a first conductive type semiconductor substrate having the first impurity region composing the charge transfer region and the second impurity region composing the separation region that are formed in its main surface, and a second conductive type third impurity region that is formed in the main surface of the first conductive type semiconductor substrate so as to have a depth larger than the first and second impurity regions, wherein the first conductive type first impurity region is formed in a main surface of the second conductive type third impurity region. In this constitution, it is possible to pull out electrons that overflow from a potential well of the first impurity region storing electrons through the second conductive type third impurity region toward the first conductive type semiconductor substrate side.

In the aforementioned solid-state image sensor according to the second aspect, preferably, the charge transfer region includes a vertical transfer region that transfers the charge in the vertical direction and a horizontal transfer region that is connected to the vertical transfer region and transfers the charge transferred from the vertical transfer region in the horizontal direction, and the transfer electrode includes a vertical transfer electrode that transfers the charge in the vertical transfer region and a horizontal transfer electrode that transfers the charge in the horizontal transfer region, and the boundary part of the charge transfer region between the first region with the first channel width and the second region with the second channel width is located in a region between the vertical transfer electrode and the horizontal transfer electrode adjacent to each other in a region where the vertical transfer region and the horizontal transfer region are connected to each other. In this constitution, in the case where, in the region where the vertical transfer region and the horizontal transfer region are connected to each other, a prescribed negative voltage is applied to the vertical transfer electrode, and a prescribed positive voltage is applied to the horizontal transfer electrode, since an electric field is generated between the vertical transfer electrode and the horizontal transfer electrode adjacent to each other toward the transfer direction of charge, the generated electric field can cancel a potential barrier that is formed in the boundary part of the charge transfer region between the first region with the first channel width and the second region with the second channel width due to increase of a narrow channel effect by an electric field from the separation region as a channel width reduces. Therefore, it is possible to suppress interference with transfer of charge from the vertical transfer region to the horizontal transfer region by the potential barrier. In addition, the boundary part of the charge transfer region between the first region with the first channel width and the second region with the second channel width is located in a region between the vertical transfer electrode and the horizontal transfer electrode adjacent to each other, thus, in the case where the second region with the smaller second channel width of the charge transfer region is located on the horizontal transfer electrode side, and charge in one vertical transfer region is transferred to a region under one horizontal transfer electrode corresponding thereto, a region with a larger width of the separation region adjacent to the second region of the vertical transfer region can effectively suppress that charge transferred to the region under the one horizontal transfer electrode flows to a region under other horizontal transfer electrode through the separation region and vicinity thereof. Therefore, it is possible to ensure to transfer charge in one vertical transfer region to a region under one horizontal transfer electrode corresponding thereto.

In the solid-state image sensor comprising the vertical transfer region and the horizontal transfer region, the vertical transfer region includes a storage part that stores signal charge, and the horizontal transfer region includes a horizontal transfer part that transfers the signal charge from the storage part to an output part, wherein the boundary part between the first region with the first channel width and the second region with the second channel width is located in a region between the vertical transfer electrode and the horizontal transfer electrode adjacent to each other in a region where the storage part and the horizontal transfer part are connected to each other. In this constitution, it is possible to suppress mixture of charge between the storage part and the horizontal transfer part to each other, and to suppress reduction of a transfer efficiency of charge.

### BRIEF DESCRIPTION OF THE DRAWINGS

FIG. 1 is a view schematically showing the whole constitution of a solid-state image sensor according to one embodiment of the present invention;

FIG. 2 is a plan view for illustrating a structure of an imaging part and a storage part of the solid-state image sensor according to the one embodiment shown in FIG. 1;

FIG. 3 is a plan view for illustrating a structure of the storage part and a horizontal part of the solid-state image sensor according to the one embodiment shown in FIG. 1;

FIG. 4 is a diagram for illustrating a state of a potential in transfer of electrons in a region where the storage part and the horizontal transfer part of the solid-state image sensor according to the one embodiment shown in FIG. 1 are connected to each other;

FIG. 5 is a cross-sectional view of the solid-state image sensor taken along a line 50-50 shown in FIG. 2;

FIG. 6 is a cross-sectional view of the solid-state image sensor taken along a line 100-100 shown in FIG. 2;

FIG. 7 is a cross-sectional view of the solid-state image sensor taken along a line 150-150 shown in FIG. 3;

FIG. 8 is a cross-sectional view of the solid-state image sensor taken along a line 200-200 shown in FIG. 3;

FIG. 9 is a correlation diagram showing the relation between a position of a boundary part where a channel width of a charge transfer path reduces and a height of a potential barrier;

FIG. 10 is a plan view for illustrating a structure of a storage part and a horizontal part of an exemplary conventional solid-state image sensor; and

FIG. 11 is a diagram for illustrating a state of a potential in transfer of electrons in a region where the storage part and the horizontal transfer part of the exemplary conventional solid-state image sensor shown in FIG. 10 are connected to each other.

### DESCRIPTION OF THE PREFERRED EMBODIMENT

An embodiment of the present invention is now described with reference to the drawings.

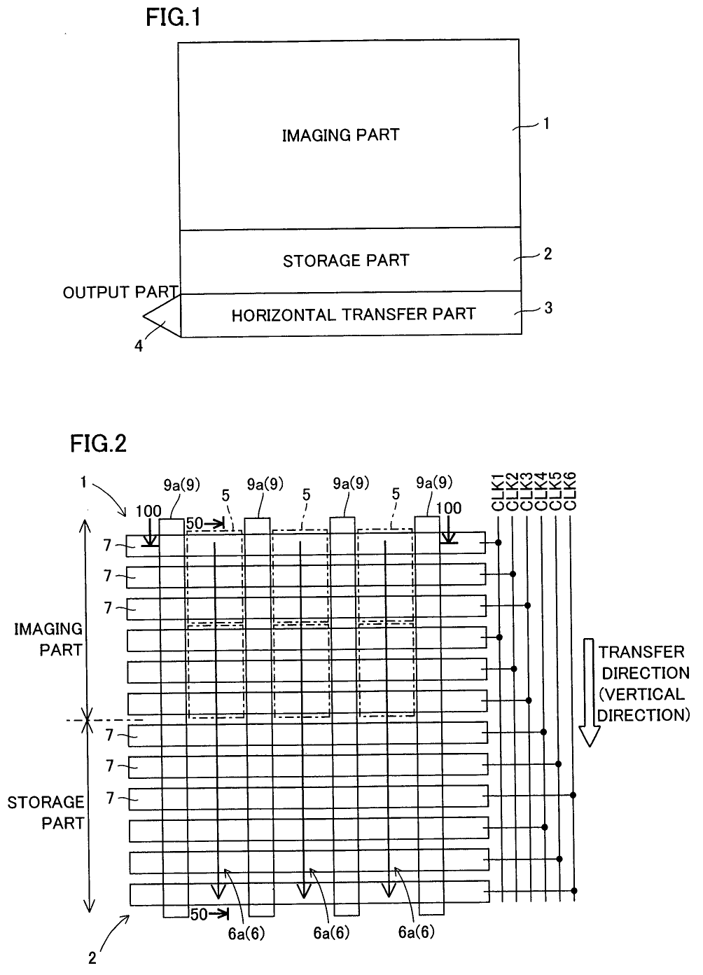

With reference to FIGS. 1 to 8, in this embodiment, an exemplary frame transfer type solid-state image sensor where the present invention is applied is described.

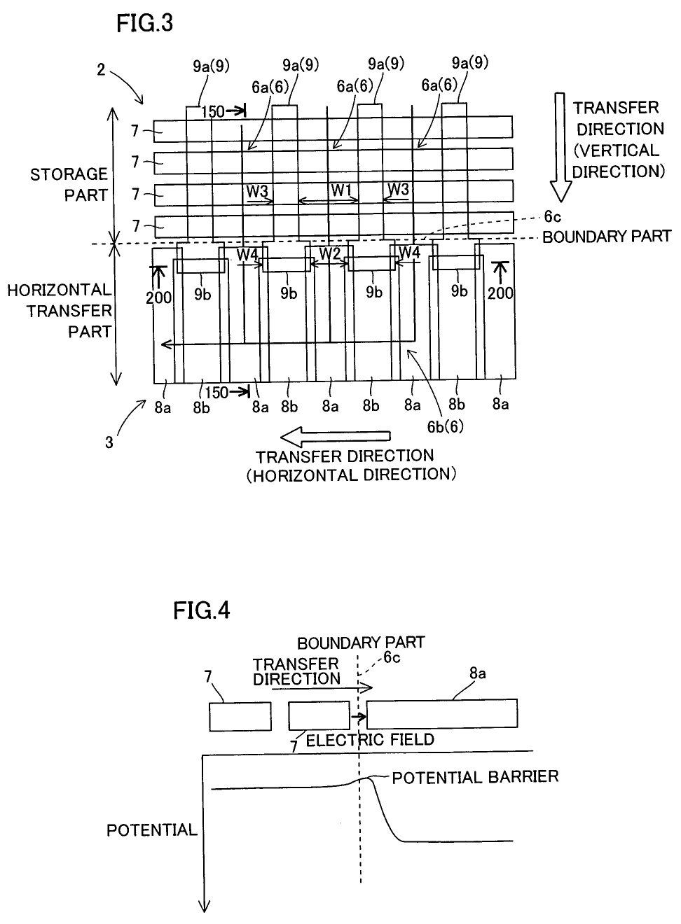

The frame transfer type solid-state image sensor according to this embodiment comprises an imaging part 1, a storage part 2, a horizontal transfer part 3, and an output part 4, as shown in FIG. 1. The imaging part 1 is provided to perform photoelectric conversion from light incident thereon. The imaging part 1 has a plurality of pixels 5 that serve to perform photoelectric conversion and are arranged in a matrix shape, as shown in FIG. 2. The imaging part 1 serves to store electrons (charge) produced due to photoelectric conversion and to transfer the electrons to the storage part 2 in the vertical direction. The storage part 2 serves to store the electrons transferred from the imaging part 1 and to transfer the electrons to the horizontal transfer part 3 (see FIG. 3) in the vertical direction. The horizontal transfer part 3 serves to sequentially transfer the electrons transferred from the storage part 2 in the horizontal direction to the output part 4 (see FIG. 1). The output part 4 serves to provide the electrons transferred from the horizontal transfer part 3 as an electrical signal.

The imaging part 1, the storage part 2 and the horizontal transfer part 3 are provided with a charge transfer path 6 composing a channel where electrons are transferred as shown in FIGS. 2 and 3. The charge transfer path 6 is composed of a plurality of vertical charge transfer paths 6a (see FIG. 2) that are provided to extend in the vertical direction in the imaging part 1, the storage part 2 and a prescribed part of the horizontal transfer part 3, and one horizontal charge transfer path 6b (see FIG. 3) that is provided to extend in the horizontal direction in the horizontal transfer part 3. The charge transfer path 6 is an example of the “charge transfer region” in the present invention. The vertical charge transfer path 6a is an example of a “vertical transfer region” in the present invention, and the horizontal charge transfer path 6b is an example of the “horizontal transfer region” in the present invention. All of the plurality of vertical charge transfer paths 6a are connected to the one horizontal charge transfer path 6b. A plurality of vertical transfer electrodes 7 for transferring electrons in the vertical charge transfer paths 6a in the vertical direction are provided in the imaging part 1 and the storage part 2 to extend in the horizontal direction. The plurality of vertical transfer electrodes 7 have a width of about 0.4 μm, and are spaced at an interval of about 0.2 μm from each other. In addition, three vertical transfer electrodes 7 are provided in each one pixel 5. While three-phase clock signals CLK1 to CLK3 for transferring electrons are provided to the three vertical transfer electrodes 7 of the imaging part 1, respectively, three-phase clock signals CLK4 to CLK6 for transferring electrons are provided to the three vertical transfer electrodes 7 of the storage part 2, respectively. In each of the imaging part 1 and the storage part 2, three vertical transfer electrodes 7 are turned to ON state one time each by the three-phase clock signals CLK1 to CLK3 or CLK4 to CLK6, thus, electrons stored in a region under a prescribed vertical transfer electrode 7 are transferred to a region under other vertical transfer electrode 7 adjacent to the prescribed vertical transfer electrode 7. In addition, a plurality of horizontal transfer electrodes 8a and 8b for transferring electrons in the horizontal charge transfer path 6b in the horizontal direction are provided in the horizontal transfer part 3 to extend in the vertical direction as shown in FIG. 3. The plurality of horizontal transfer electrodes 8a and 8b receive clock signals, respectively. The plurality of horizontal transfer electrodes 8a and 8b are turned to ON state one time each by the clock signals, thus, electrons stored in a region under a prescribed horizontal transfer electrode 8a (8b) are successively transferred to a region under other horizontal transfer electrode 8b (8a) adjacent to the prescribed horizontal transfer electrode 8a (8b).

A plurality of p-type channel stop regions 9 that are arranged so as to interpose the vertical charge transfer path 6a between them are provided in the imaging part 1, the storage part 2 and the horizontal transfer part 3 to extend in the horizontal direction. The p-type channel stop region 9 is an example of a “separation region” in the present invention. The p-type channel stop region 9 is composed of a region 9 that is provided in the imaging part 1 and the storage part 2 and has a width W3 of about 0.3 μm, and a region 9b that is provided in the horizontal transfer part 3 and has a width W4 of about 0.4 μm to about 0.7 μm. The region 9b with the width W4 (about 0.4 μm to about 0.7 μm) larger than the p-type channel stop region 9 (width W3: about 0.3 μm) is provided in order to suppress that electrons in two adjacent vertical charge transfer paths 6a that interpose the region 9b of the p-type channel stop region 9 between them are mixed. Due to the region 9b of the p-type channel stop region 9 with the width W4, electrons in one vertical charge transfer path 6a of the storage part 2 do not flow in the horizontal direction but is transferred into a region under one horizontal transfer electrode Ba corresponding thereto. The vertical charge transfer path 6a between two p-type channel stop regions adjacent to each other in the imaging part 1 and the storage part 2 has a width W1 of about 1.5 μm, and the vertical charge transfer path 6a between two p-type channel stop regions adjacent to each other in the horizontal transfer part 3 has a width W2 of about 1.1 μm to about 1.4 μm. That is, the width W2 of the vertical charge transfer path 6a in the horizontal transfer part 3 is smaller than the width W1 of the vertical charge transfer path 6a in the imaging part 1 and the storage part 2. In a boundary part 6c between a region of the vertical charge transfer path 6a in the storage part 2 and a region of the vertical charge transfer path 6a in the horizontal transfer part 3, because of increase of a narrow channel effect by an electric field from the adjacent p-type channel stop regions 9 due to the reduction of channel width of the vertical charge transfer path 6a, a potential barrier shown in FIG. 4 is formed. Note that FIG. 4 shows a potential state when a negative voltage of about −5.8 V is applied to the vertical transfer electrode 7, and a positive voltage of about 2.9 V is applied to the horizontal transfer electrode 8a.

In this embodiment, as shown in FIG. 3, the boundary part 6c between a region of the vertical charge transfer path 6a in the storage part 2 and a region of the vertical charge transfer path 6a in the horizontal transfer part 3 is located in a region where the storage part 2 and the horizontal transfer part 3 are connected to each other in a region between the vertical transfer electrode 7 and the horizontal transfer electrode 8a adjacent to each other. In this embodiment, in the final step where electrons are transferred from the storage part 2 to the horizontal transfer part 3, a negative voltage of about −5.8 V is applied to the vertical transfer electrode 7 of the final stage of the storage part 2, and a positive voltage of about 2.9 V is applied to the horizontal transfer electrode 8a. In this case, the negative voltage (about −5.8 V) applied to the vertical transfer electrode 7 has an absolute value larger than the positive voltage (about 2.9 V) applied to the horizontal transfer electrode 8a. In addition, a negative voltage is applied to the vertical transfer electrode 7, and a positive voltage is applied to the horizontal transfer electrode 8a, thus, in the final step where electrons are transferred from the storage part 2 to the horizontal transfer part 3, an electric field is generated in the transverse direction along a transfer direction of electrons from the vertical transfer electrode 7 of the final stage of the storage part 2 toward the horizontal transfer electrode 8a of the horizontal transfer part 3 side. The electric field cancels the aforementioned potential barrier that is formed in the boundary part 6c between a region of the vertical charge transfer path 6a in the storage part 2 and a region of the vertical charge transfer path 6a in the horizontal transfer part 3.

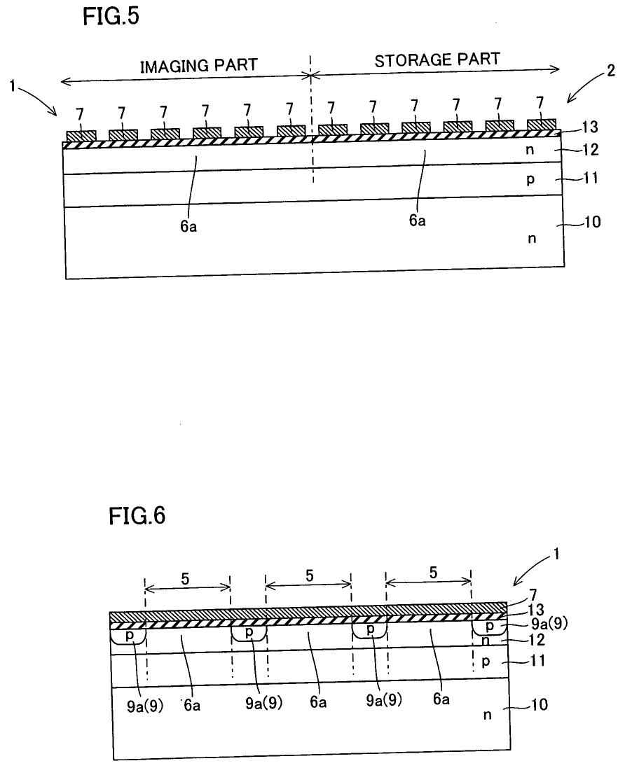

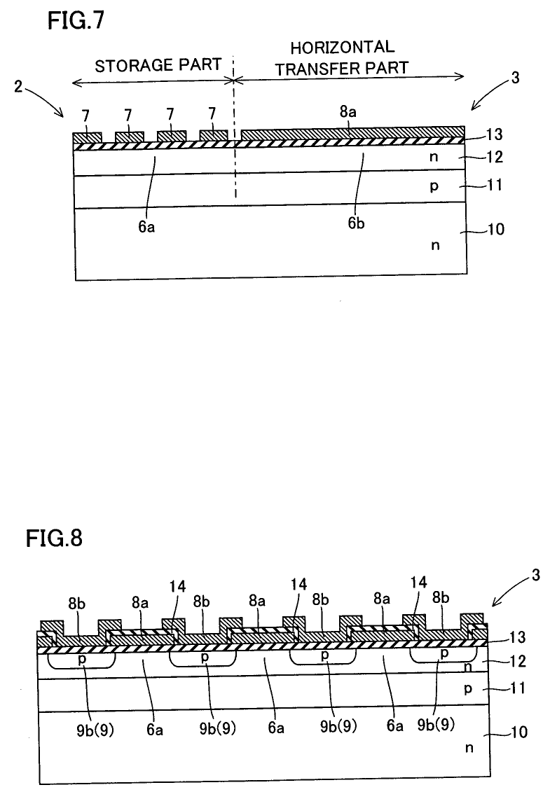

As shown in FIGS. 5 to 8, a p-type impurity region 11 that has a depth of about 2 μm to about 4 μm from the surface of an n-type silicon substrate 10 and an impurity concentration of about 10¹⁵ cm⁻³ is formed in the imaging part 1, the storage part 2 and the horizontal transfer part 3. In addition, an n-type impurity region 12 that has a depth of about 0.5 μm to about 1.0 μm from the surface of the n-type silicon substrate 10 and an impurity concentration of about 5×10¹⁵ cm⁻³ to about 5×10¹⁶ cm⁻³ is formed. A voltage of about 7 V is applied to the n-type silicon substrate 10. The n-type silicon substrate 10, the p-type impurity region 11 and the n-type impurity region 12 compose a vertical overflow drain structure that carries off electrons overflowing from a potential well storing electrons toward the n-type silicon substrate 10 side. As shown in FIGS. 6 and 8, the aforementioned plurality of p-type channel stop regions 9 are formed in the surface of the n-type impurity region 12. The aforementioned vertical charge transfer path 6a is formed in a region between two p-type channel stop regions 9 adjacent to each other in the n-type impurity region 12. As shown in FIG. 7, the aforementioned horizontal charge transfer path 6b is formed in the n-type impurity region 12 of the horizontal transfer part 3. An insulating film 13 consisting of SiO₂ is formed on the n-type impurity region 12 and the p-type channel stop region 9 of the n-type silicon substrate 10. Additionally, in the imaging part 1 and the storage part 2, as shown in FIG. 5, the aforementioned plurality of vertical transfer electrodes 7 are formed on the insulating film 13. Furthermore, in the horizontal transfer part 3, as shown in FIG. 8, the aforementioned plurality of horizontal transfer electrodes 8a and 8b are formed on the insulating film 13. Moreover, an end of the horizontal transfer electrode 8b adjacent to the horizontal transfer electrode 8a along the transfer direction of electrons (horizontal direction) overlaps the horizontal transfer electrode 8a so as to interpose an insulating film 14 between them.

In this embodiment, since, in the region where the storage part 2 and the horizontal transfer part 3 are connected to each other, the boundary part 6c of the vertical charge transfer path 6a between a region with the channel width W1 and a region with the channel width W2 smaller than the channel width W1 is located in a region between the vertical transfer electrode 7 of the final stage of the storage part 2 and the horizontal transfer electrode 8a adjacent to each other as mentioned above, in the final step where electrons are transferred, when a negative voltage of about −5.8 V is applied to the vertical transfer electrode 7 of the final stage of the storage part 2, and a positive voltage of about 2.9 V is applied to the horizontal transfer electrode 8a, an electric field is generated between the vertical transfer electrode 7 of the final stage of the storage part 2 and the horizontal transfer electrode 8a adjacent to each other toward the transfer direction of electron (vertical direction). The generated electric field can cancel a potential barrier that is formed in the boundary part 6c of the vertical charge transfer path 6a between the region with the channel width W1 and the region with the channel width W2 due to increase of a narrow channel effect by an electric field from the p-type channels stop region 9 as a channel width reduces. Therefore, since interference with transfer of electrons from the storage part 2 to the horizontal transfer part 3 by the potential barrier can be suppressed, it is possible to suppress reduction of a transfer efficiency of electrons.

Furthermore, in this embodiment, the boundary part 6c of the vertical charge transfer path 6a between the region with the channel width W1 and the region with the channel width W2 smaller than the channel width W1 is located in the region between the vertical transfer electrode 7 and the horizontal transfer electrode 8a adjacent to each other, and the region with the small channel width W2 of the vertical charge transfer path 6a is located on the horizontal transfer electrode 8a side, thus, due to the region 9b with the large width W4 of the p-type channel stop region 9 adjacent to the region with the small channel width W2 of the vertical charge transfer path 6a, it is possible to effectively suppress that electrons transferred from a region of one vertical charge transfer path 6a in the storage part 2 to a region under one horizontal transfer electrode 8a corresponding thereto flow into a region under other horizontal transfer electrode 8a through the p-type channel stop region 9a and vicinity thereof. Therefore, it is possible to ensure to transfer electrons in one vertical charge transfer path 6a of the storage part 2 to a region under one horizontal transfer electrode 8a of the horizontal transfer part 3 corresponding thereto.

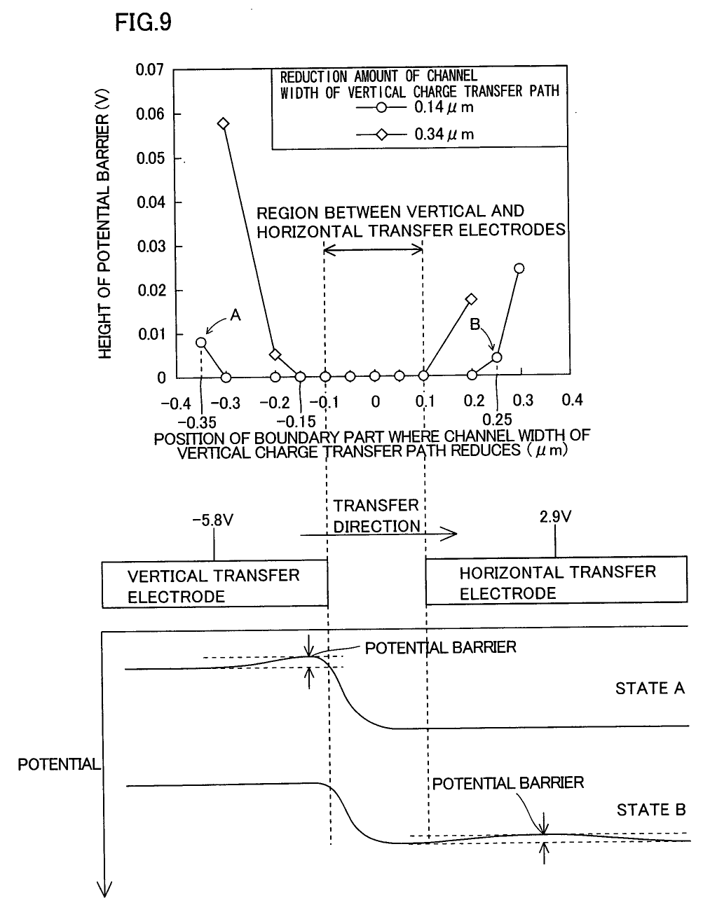

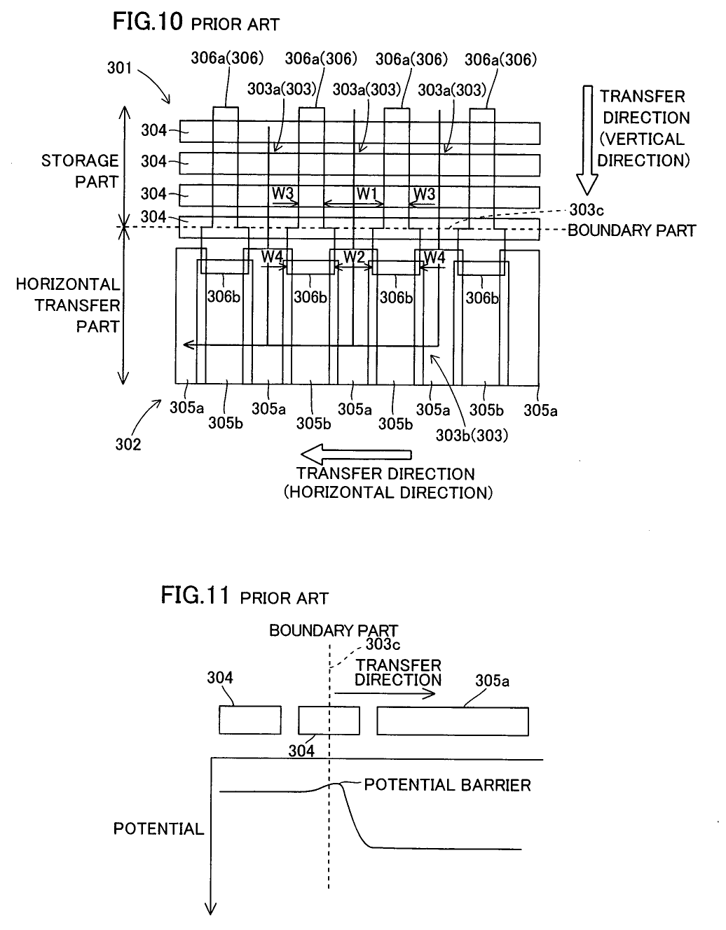

Simulation that is conducted to confirm effects of the foregoing embodiment is now described. In the simulation, as a position of a boundary part where a channel width of a vertical charge transfer path between two p-type channel stop regions adjacent to each other reduces moves along a transfer direction of electrons, a height of a potential barrier formed in the boundary part is calculated. The result is shown in FIG. 9. Note that, in a graph of FIG. 9, the horizontal axis shows the center in a region between a vertical transfer electrode and a horizontal transfer electrode as 0 μm, the horizontal transfer electrode side from the center as the positive side (0 μm to 0.4 μm), and the vertical transfer electrode side from the center as the negetive side (−0.4 μm to 0 μm). In addition, the vertical axis in the graph of FIG. 9 shows a height of a potential barrier. In the simulation, an interval between the vertical transfer electrode and the horizontal transfer electrode is set to 0.2 μm (−0.1 μm to 0.1 μm). Thus, while, in the range of −0.4 μm to −0.1 μm in FIG. 9, the boundary part where a channel width of the vertical charge transfer path reduces is located under the vertical transfer electrode, in the range of 0.1 μm to 0.4 μm in FIG. 9, the boundary part where a channel width of the vertical charge transfer path reduces is located under the horizontal transfer electrode. In addition, setting is performed such that a negative voltage of −5.8 V is applied to the vertical transfer electrode, and a positive voltage of 2.9 V is applied to the horizontal transfer electrode. Additionally, simulation is conducted in the cases where a channel width of the vertical charge transfer path reduces 0.14 μm and 0.34 μm in the boundary part where a channel width of the vertical charge transfer path reduces.

With reference to FIG. 9, in the case where the boundary part where a channel width of the vertical charge transfer path reduces is located in a region between the vertical transfer electrode and the horizontal transfer electrode (−0.1 μm and 0.1 μm), it is found that a height of a potential barrier is 0 V in the both cases of 0.14 μm and 0.34 μm of a reduction amount of a channel width of the vertical charge transfer path. That is, in the case where the boundary part where a channel width of the vertical charge transfer path reduces is located in a region between the vertical transfer electrode and the horizontal transfer electrode (−0.1 μm and 0.1 μm), it is found that a potential barrier is not formed in the both cases of 0.14 μm and 0.34 μm as the reduction amount of a channel width of the vertical charge transfer path. In addition, with reference to FIG. 9, in the case where the boundary part where a channel width of the vertical charge transfer path reduces is located at a position of 0.05 μm on the side under the vertical transfer electrode from an end of the vertical transfer electrode (position of −0.15 μm), it is found that a height of a potential barrier is also 0 V in the both cases of 0.14 μm and 0.34 μm of a reduction amount of a channel width of the vertical charge transfer path. That is, in the case where the boundary part where a channel width of the vertical charge transfer path reduces is located in a region in the vicinity of a position beneath the end on the horizontal transfer electrode side of the vertical transfer electrode, it is found that formation of a potential barrier can be also suppressed in the both cases of 0.14 μm and 0.34 μm as the reduction amount of a channel width of the vertical charge transfer path. The reason is considered that since a positive voltage of 2.9 V is applied to the horizontal transfer electrode, and a negative voltage of −5.8 V with an absolute value larger than 2.9 V is applied to the vertical transfer electrode, an electric field that is generated between the vertical transfer electrode and the horizontal transfer electrode toward the transfer direction of charge also affects the region in the vicinity of a position beneath the end on the horizontal transfer electrode side of the vertical transfer electrode, and thus cancels a potential barrier.

In the case of 0.14 μm as the reduction amount of a channel width of the vertical charge transfer path in the boundary part, in a state A where the boundary part where a channel width of the vertical charge transfer path reduces is located at a position of 0.25 μm on the side under the vertical transfer electrode from an end on the horizontal transfer electrode side of the vertical transfer electrode (−0.35 μm), it is found that a potential barrier is formed. In the state A, as shown in a potential diagram of FIG. 9, a potential barrier is formed in a region under the vertical transfer electrode. In the case of 0.34 μm as the reduction amount of a channel width of the vertical charge transfer path in the boundary part, in the case where the boundary part where a channel width of the vertical charge transfer path reduces is located at a position of 0.1 μm or more on the side under the vertical transfer electrode from an end on the horizontal transfer electrode side of the vertical transfer electrode (−0.3 μm to −0.2 μm), it is found that a potential barrier is formed. Additionally, in the case of 0.14 μm as the reduction amount of a channel width of the vertical charge transfer path in the boundary part, in the case where the boundary part where a channel width of the vertical charge transfer path reduces is located at a position of 0.15 μm or more on the side under the horizontal transfer electrode from the end on the vertical transfer electrode side of the horizontal transfer electrode (0.25 μm to 0.3 μm), it is found that a potential barrier is formed.

In this case, for example, as a state B in FIG. 9 where the boundary part where a channel width of the vertical charge transfer path reduces is located at a position of 0.15 μm on the side under the horizontal transfer electrode from the end on the vertical transfer electrode side of the horizontal transfer electrode (0.25 μm), a potential barrier is formed in a region under the horizontal transfer electrode. In this case, since the potential barrier that is formed in a region under the horizontal transfer electrode interferences with transfer of charge, a transfer efficiency of electrons also reduces. Additionally, in the case of 0.34 μm as the reduction amount of a channel width of the vertical charge transfer path in the boundary part, when the boundary part where a channel width of the vertical charge transfer path reduces is located at a position of 0.1 μm on the side under the horizontal transfer electrode from the end on the vertical transfer electrode side of the horizontal transfer electrode (0.2 μm), it is found that a potential barrier is formed. In this case, similarly to the case of 0.14 μm as the reduction amount of a channel width of the vertical charge transfer path in the boundary, a potential barrier is formed in the region under the horizontal transfer electrode.

It should be appreciated, however, that the embodiment described above are illustrative, and the invention is not specifically limited to description above. The invention is defined not by the foregoing description of the embodiment, but by the appended claims, their equivalents, and various modifications that can be made without departing from the scope of the invention as defined in the appended claims.

In the foregoing embodiment, the case where the present invention is applied to a frame transfer type solid-state image sensor is described, however, the present invention is not limited to this case. For example, the present invention is applied to a solid-state image sensor other than a frame transfer type solid-state image sensor.

Furthermore, in the foregoing embodiment, the boundary part where a channel width of the vertical charge transfer path reduces is located in an intermediate location in a region between the vertical transfer electrode and the horizontal transfer electrode adjacent to each other, however, the present invention is not limited to this arrangement. The boundary part where a channel width of the vertical charge transfer path reduces may be located in a location closer to an end of the vertical transfer electrode relative to the intermediate location between the vertical transfer electrode and the horizontal transfer electrode adjacent to each other. In this constitution, in the final step where electrons are transferred, when and a positive voltage is applied to the horizontal transfer electrode, and a negative voltage with an absolute value of the voltage larger than the positive voltage of the horizontal transfer electrode is applied to the vertical transfer electrode, since an electric field toward the transfer direction of electrons increases as closer to the end of the vertical transfer electrode in between the vertical transfer electrode and the horizontal transfer electrode adjacent to each other, it is possible to apply a larger electric field toward the transfer direction of electrons to the boundary part of the vertical charge transfer path that is located in a location closer to the end of the vertical transfer electrode relative to the intermediate location between the vertical transfer electrode and the horizontal transfer electrode adjacent to each other. Therefore, it is possible to further ensure to cancel a potential barrier that is formed in the boundary part of the vertical charge transfer path.

Still furthermore, in the foregoing embodiment, the boundary part where a channel width of the vertical charge transfer path reduces is located in a region between the transfer electrode of the final stage of the storage part and the horizontal transfer electrode of the horizontal transfer part, however, the present invention is not limited to this arrangement. The boundary part where a channel width of the vertical charge transfer path reduces may be located in a region between a vertical transfer electrode of the stage previous to the final stage of the storage part and a vertical transfer electrode of the stage subsequent to the vertical transfer electrode. In this constitution, since, depending on a region with a small channel width of the vertical charge transfer path, a length of a region with a large width of the p-type channel stop region along the transfer direction of electrons can be longer, it is possible to further ensure to suppress mixture of electrons in two vertical charge transfer paths adjacent to each other that interpose the p-type channel stop region between them.

Moreover, in the foregoing embodiment, the insulating film consisting of SiO₂ is used, the present invention is not limited to this constitution. An insulating film containing a material other than SiO₂ may be used. For example, an insulating film consisting of a SiN film, a multilayer film containing a SiO₂ layer and a SiN layer may be used.

What is claimed is:

1. A solid-state image sensor comprising:
a plurality of transfer electrodes that are arranged in a charge transfer region composing a channel for transferring charge and transfer the charge, and
a plurality of separation regions that are arranged so as to interpose said charge transfer region between them, wherein
said charge transfer region includes a first region with a first channel width, and a second region with a second channel width smaller than said first channel width, and a boundary part of said charge transfer region between said first region with said first channel width and said second region with said second channel width is located in a region between two of said transfer electrodes adjacent to each other.

2. The solid-state image sensor according to claim 1, wherein the second region with the second channel width smaller than said first channel width is located on a transfer direction side relative to the first region with said first channel width.

3. The solid-state image sensor according to claim 1, wherein said separation region includes a region with a first width that is provided adjacent to the first region with said first channel width of said charge transfer region, and a region with a second width larger than said first width that is provided adjacent to the second region with said second channel width of said charge transfer region.

4. The solid-state image sensor according to claim 1, wherein in transfer of said charge, a positive voltage is applied to said transfer electrode on a transfer direction side of said charge of said two of the transfer electrodes adjacent to each other, and a negative voltage with an absolute value of the voltage larger than said positive voltage is applied to said transfer electrode on the opposite side of the transfer direction side of said charge of said two of the transfer electrodes adjacent to each other.

5. The solid-state image sensor according to claim 1, wherein the boundary part of said charge transfer region between said first region with said first channel width and said second region with said second channel width is located in a location closer to an end of said transfer electrode on the opposite side of a transfer direction of said charge relative to an intermediate location between said two of the transfer electrodes adjacent to each other.

6. The solid-state image sensor according to claim 1, wherein said charge transfer region is composed of a first conductive type first impurity region, and
said separation region is composed of a second conductive type second impurity region.

7. The solid-state image sensor according to claim 6, wherein the sensor further comprises a first conductive type semiconductor substrate having the first impurity region composing said charge transfer region and the second impurity region composing said separation region that are formed in its main surface, and a second conductive type third impurity region that is formed in the main surface of said first conductive type semiconductor substrate so as to have a depth larger than said first and second impurity regions, wherein
said first conductive type first impurity region is formed in a main surface of said second conductive type third impurity region.

8. The solid-state image sensor according to claim 1, wherein said charge transfer region includes a vertical transfer region that transfers said charge in the vertical direction and a horizontal transfer region that is connected to said vertical transfer region and transfers said charge transferred from said vertical transfer region in the horizontal direction, and
said transfer electrode includes a vertical transfer electrode that transfers said charge in said vertical transfer region and a horizontal transfer electrode that transfers said charge in said horizontal transfer region, wherein
the boundary part of said charge transfer region between said first region with said first channel width and said second region with said second channel width is located in a region between said vertical transfer electrode and said horizontal transfer electrode adjacent to each other in a region where said vertical transfer region and said horizontal transfer region are connected to each other.

9. The solid-state image sensor according to claim 8, wherein said vertical transfer region includes a storage part that stores signal charge, and
said horizontal transfer region includes a horizontal transfer part that transfers the signal charge from said storage part to an output part, wherein
the boundary part between said first region with said first channel width and said second region with said second channel width is located in a region between said vertical transfer electrode and said horizontal transfer electrode adjacent to each other in a region where said storage part and said horizontal transfer part are connected to each other.

10. The solid-state image sensor according to claim 9, wherein said second region is formed to extend to a region under said horizontal transfer electrode of said horizontal transfer part.

11. A solid-state image sensor comprising:
a plurality of transfer electrodes that are arranged in a charge transfer region composing a channel for transferring charge and transfer the charge;
a plurality of separation regions that are arranged so as to interpose said charge transfer region between them, wherein
said charge transfer region includes a first region with a first channel width, and a second region with a second channel width smaller than said first channel width, and
a boundary part of said charge transfer region between said first region with said first channel width and said second region with said second channel width is located in a region between two of the transfer electrodes adjacent to each other, or in a region in the vicinity of a position beneath an end of said transfer electrode on the opposite side of a transfer direction of said charge relative to said two of the transfer electrodes adjacent to each other.

12. The solid-state image sensor according to claim 11, wherein the boundary part of said charge transfer region between said first region with said first channel width and said second region with said second channel width is located in the region in the vicinity of the position beneath the end of said transfer electrode on the opposite side of the transfer direction of said charge relative to said two of the transfer electrodes adjacent to each other.

13. The solid-state image sensor according to claim 11, wherein the boundary part of said charge transfer region between said first region with said first channel width and said second region with said second channel width is located in a location closer to the end of said transfer electrode on the opposite side of the transfer direction of said charge relative to an intermediate location between said two of the transfer electrodes adjacent to each other.

14. The solid-state image sensor according to claim 11, wherein the second region with the second channel width smaller than said first channel width is located on a transfer direction side relative to the first region with said first channel width.

15. The solid-state image sensor according to claim 11, wherein said separation region includes a region with a first width that is provided adjacent to the first region with said first channel width of said charge transfer region, and a region with a second width larger than said first width that is provided adjacent to the second region with said second channel width of said charge transfer region.

16. The solid-state image sensor according to claim 11, wherein in transfer of said charge, a positive voltage is applied to said transfer electrode on a transfer direction side of said charge of said two of the transfer electrodes adjacent to each other, and a negative voltage with an absolute value of the voltage larger than said positive voltage is applied to said transfer electrode on the opposite side of the transfer direction side of said charge of said two of the transfer electrodes adjacent to each other.

17. The solid-state image sensor according to claim 11, wherein said charge transfer region is a first conductive type first impurity region, and
said separation region is a second conductive type second impurity region.

18. The solid-state image sensor according to claim 17, wherein the sensor further comprises a first conductive type semiconductor substrate having the first impurity region composing said charge transfer region and the second impurity region composing said separation region that are formed in its main surface, and a second conductive type third impurity region that is formed in the main surface of said first conductive type semiconductor substrate so as to have a depth larger than said first and second impurity regions, wherein
said first conductive type first impurity region is formed in a main surface of said second conductive type third impurity region.

19. The solid-state image sensor according to claim 11, wherein said charge transfer region includes a vertical transfer region that transfers said charge in the vertical direction and a horizontal transfer region that is connected to said vertical transfer region and transfers said charge transferred from said vertical transfer region in the horizontal direction, and
said transfer electrode includes a vertical transfer electrode that transfers said charge in said vertical transfer region and a horizontal transfer electrode that transfers said charge in said horizontal transfer region, wherein
the boundary part of said charge transfer region between said first region with said first channel width and said second region with said second channel width is located in a region between said vertical transfer electrode and said horizontal transfer electrode adjacent to each other in a region where said vertical transfer region and said horizontal transfer region are connected to each other.

20. The solid-state image sensor according to claim 19, wherein said vertical transfer region includes a storage part that stores signal charge, and
said horizontal transfer region includes a horizontal transfer part that transfers the signal charge from said storage part to an output part, wherein
the boundary part between said first region with said first channel width and said second region with said second channel width is located in a region between said vertical transfer electrode and said horizontal transfer electrode adjacent to each other in a region where said storage part and said horizontal transfer part are connected to each other.
